(19) United States
(12) Patent Application Publication
(10) Pub. No.: US 2026/0246172 A1
(43) Pub. Date: Aug. 20, 2026

(54) Electronics Connector

(71) Applicant: Schaeffler Technologies AG & Co. KG, Herzogenaurach (DE)

(72) Inventors: Ravi Kiran Kothamasa, Lake Orion, MI (US); Robert BABULA, NEW BRAUNFELS, TX (US); Leonardo Haova Ramon Salazar, Zapopan (MX)

(73) Assignee: Schaeffler Technologies AG & Co. KG, Herzogenaurach (DE)

(21) Appl. No.: 19/490,578

(22) PCT Filed: May 17, 2024
(86) PCT No.: PCT/US2024/029934

§ 371 Date: Dec. 5, 2025

Related U.S. Application Data
(60) Provisional application No. 63/503,083, filed on May 18, 2023.

(51) Int. Cl. H01R 12/51; H01R 4/02; H05K 1/181

(52) U.S. Cl. CPC H01R 12/51; H01R 4/029; H05K 1/181; H05K 2201/10189; H05K 2201/10272

(57) ABSTRACT

The disclosure provides a connector for connecting a first element and a second element. The connector includes a first section having a first length. The first section is configured for attachment to the first element. The connector also includes a second section having a second length. The second length is greater than the first length. The second section is configured for attachment to the second element. The connector includes a connection section connecting the first section and the second section such that the first section and the second section are each extending away from the connection section.

### TECHNICAL FIELD

The disclosure relates to a connector for connecting a first element and a second element used in electronics, such as vehicle electronics.

### BACKGROUND

A PCB (printed circuit board) mechanically supports and electrically connects electronic components using conductive pathways, tracks or signals etched from copper sheets laminated onto a non-conductive substrate. PCBs are used in almost all electronic products. Busbars are crucial in electrical distribution systems because they distribute power efficiently, thus reducing energy consumption. Aside from power conduction and distribution, busbar designs are vital for thermal management in electric vehicles. Eliminating busbars from electric vehicles results in overheating of the vehicle due to the tremendous heat generated in the vehicle batteries. Therefore, there is a need for a robust, low-cost component that connects a PCB to the busbar, for example, in electric vehicle.

### SUMMARY

A first aspect of the disclosure provides a connector for connecting a first element and a second element. The connector includes first section having a first length. The first section is configured to attach to the first element. The connector also includes a second section having a second length. In some examples, the second length is greater than the first length. The second section is configured to attach to the second element. The connector also includes a connection section connecting the first section and the second section such that the first section and the second section are each extending away from the connection section.

Implementations of the disclosure may include one or more of the following optional features. In some implementations, the first element is a PCB. The second element may be a busbar.

In some examples, the first section is substantially parallel to the second section. The first section may include a first inner side and a first outer side. The second section may include a second inner side and a second outer side. The first inner side faces the second inner side. In some examples, the first inner side, the second inner side, and a connector inner side define a receptacle. The second inner side of the second section includes a distal end for attachment to the second element. In some examples, at least a portion of the first outer side of the first section is configured for attachment to the first element.

Another aspect of the disclosure provides a method of connecting a first element and a second element by way of a connector. The method includes: providing the first element having a first connection area; providing the second element having a second connection area; and providing the connector for connecting the first element and the second element. The connector includes a first section, a second section, and a connection section between the first section and the second section. The method also includes connecting at least a portion of the first section of the connector with the first connection area of the first element; and connecting at least a portion of the second section of the connector with the second connection area of the second element.

Implementations of this aspect of the disclosure may include one or more of the following optional features. In some implementations, connecting the portion of the first section of the connector with the first connection area includes soldering the portion of the first section of the connector with the first connection area. In some examples, connecting the portion of the second section of the connector with the second connection area includes welding the portion of the second section of the connector with the second connection area.

In some examples, providing the connector for connecting the first element and the second element includes: providing a tape reel having multiple connectors; and removing one of the multiple connectors from the tape reel as the connector. The first element may be a PCB; the second element may be a busbar.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 is a schematic view of an exemplary connector.

FIG. 2 is a side view of the exemplary connector shown in FIG. 1.

FIG. 3 is a schematic view of the connector of FIG. 1, where the connector is connected to a first element.

FIG. 4 is a schematic view of the connector of FIG. 3, where the connector is connected to the first element and a second element.

FIGS. 5 and 6 are schematic views of the connector of FIG. 1 connecting two elements.

FIG. 7 is a schematic view of an exemplary arrangement of operations for connecting a first element and a second element by way of a connector.

Like reference symbols in the various drawings indicate like elements.

### DETAILED DESCRIPTION

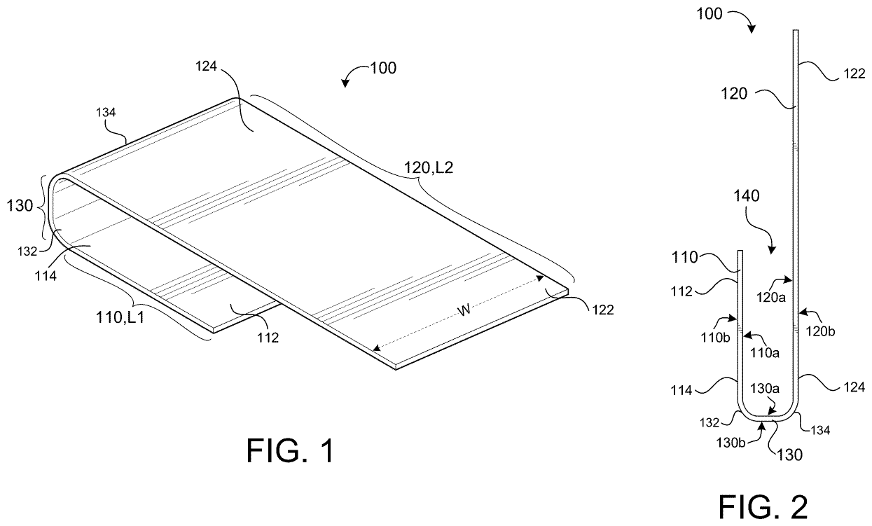

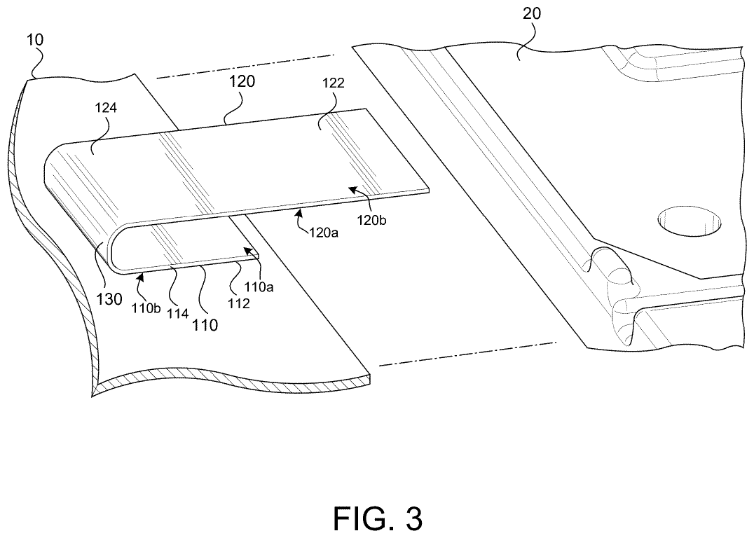

The disclosure provides a connector component 100 that is robust and low-cost and may be used in several electronic applications, including, but not limited to battery management system. Referring to FIGS. 1-3, the connector 100, also referred to as a connector or a J-clip, connects a first element 10 with a second element 20. In some examples, the first element 10 is a printed circuit board (PCB) and the second element 20 is a busbar. The connector 100 may be used to connect other elements as well. The connector 100 includes a first section 110, a second section 120, and a connection section 130. The first section 110 includes a distal end 112 and a proximal end 114. The distal end 112 extends away from the proximal end 114 which is adjacent to the connection section 130. The first section 110 includes an inner side 110a and an outer side 110b, where in the inner side 110a is opposite the outer side 110b, and the outer side 110b faces away from the connector 100. The first section 110 has a first length L1.

The second section 120 includes a distal end 122 and a proximal end 124, where the distal end 122 extends away from the proximal end 124 which is adjacent to the connection section 130. The second section 120 includes an inner side 120a and an outer side 120b, where in the inner side 120a is opposite the outer side 120b, and the outer side 120b faces away from the connector 100. The inner side 110a of the first section 110 faces the inner side 120a of the second section 120. In some examples, the first section 110 and the second section 120 extend substantially parallel to each other in a direction away from the connection section 130. The second section 120 has a second length L2 being greater than the first length L1 of the first section 110.

The connection section 130 has an inner side 130a and an outer side 130b being opposite to the inner side 130a and facing away from the connector 100. The connection section 130 includes a curve at each end such that the first section 110 and the second section 120 extend away from the connection section 130. In some examples, the connection section 130 includes a first curve 132 and a second curve 134. The first curve 132 is adjacent to the first section 110, where the first section 110 extends away from the first curve 132. The second curve 134 is adjacent to the second section 120, where the second section 120 extends away from the second curve 134. The inner side 110a, 120a, 130a of each of the first section 110, second section 120, and the connection section 130 define a receptacle 140.

In some examples, each of the first section 110, second section 120, and the connection section 130 define a width W. In other examples, the width Wis a variable width that changes along each one of the first section 110, second section 120, and the connection section 130.

In some implementations, the connector 100 includes a sheet metal component made of Aluminum with Nickle (Ni) and Tin (Sn) plating. The connector 100 may be made of other materials, such as, but not limited to, pure Ni (Nickle). In some examples, the connector 100 is designed such that a center of mass of the connector 100 is determined to prevent the connector 100 from tipping towards the distal end 122 of the second section 120 when the connector 100 is placed on the first outer side 110b of the first section 110. As such, the connector 100 is more stable when being connected to the first element 10.

In some examples, a tape reel includes a plurality of connectors 100. During manufacturing process, each connector 100 is removed from the tape reel and used to connect the PCB 10 and the busbar 20. Connecting the PCB 10 and the busbar 20 may be implemented by an automated system without any human touch. In this case, the automated system selects a connector 100 from the tape reel and uses it to connect the PCB 10 and the busbar 20.

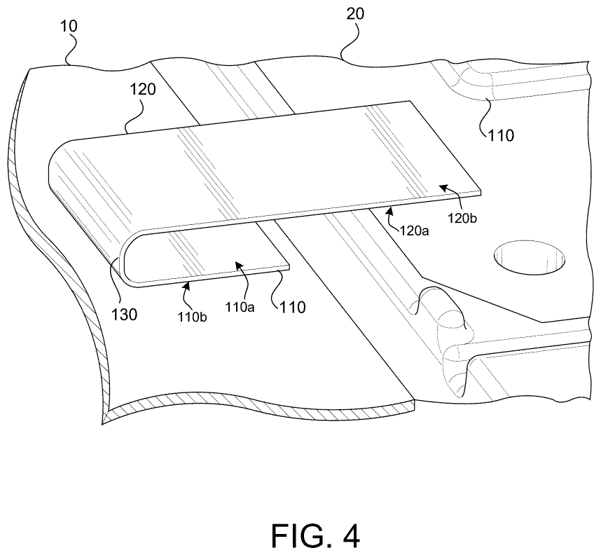

The connector 100 is then soldered to the PCB 10 using Surface Mount Technology (SMT). SMT is a method in which an electrical component, such as the connector 100, is mounted directly onto the surface of the PCB 10. SMT allows for increased manufacturing automation and therefore reduces cost and mainly improves quality. The PCB 10 includes a flat area referred to solder pads. In some examples, a substance such as a solder paste is applied to the solder pads of the PCB 10. Once the substance (i.e., solder paste) is applied, an automated machine may be used to remove the connector 100, for example, from the tape reel, and place the connector 100 on the solder pad of the PCB. In some examples, the SMT process includes additional steps to complete the soldering process. FIG. 3 shows the connector 100 soldered to the PCB 10. More specifically, as can be seen, the first outer side 110b of the first section 110 is soldered to the PCB 10. In other examples, a portion of the first outer side 110b of the first section 110 is soldered to the PCB 10. Due to the center of mass of the connector 100, the SMT method may be applied to the connector 100.

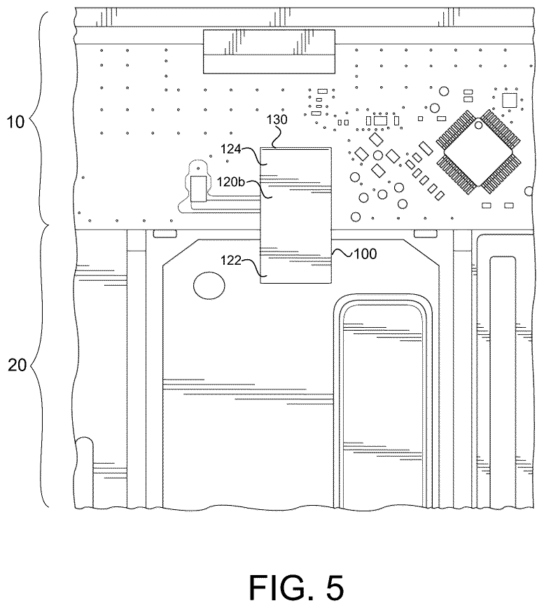

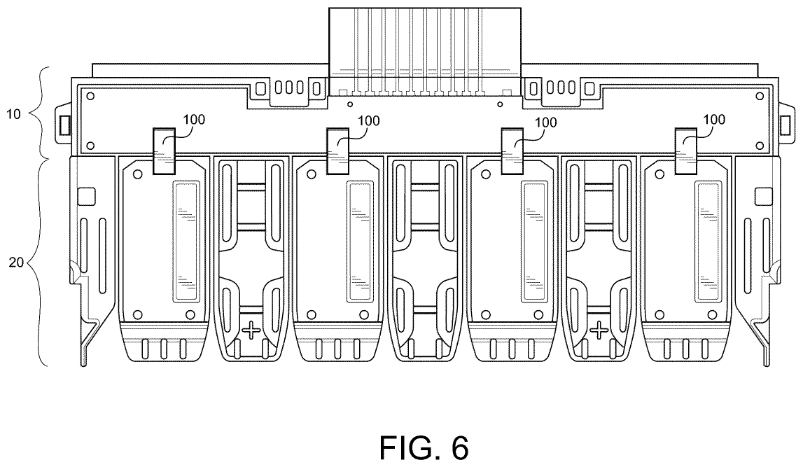

Following, the second section 120 of the connector 100 is welded to the busbar 20, thus completing the connection between the PCB 10 and the busbar 20. More specifically, the inner side 120a of the distal end 122 of second section 120 is welded to the busbar 20 as can be seen in FIGS. 4-6. The PCB 10 and the busbar 20 are on different planes. Therefore, the connector 100 can accommodate the PCB 10 and the busbar 20 that are not on the same plane. Additionally, the difference in length between the first section 110 having the first length L1 and the second section 120 having the second length L2 allows for flexibility with a span and a height change between the PCB 10 and the busbar 20. Furthermore, the curvature of the connection section 130 has a bending capability allowing for flexibility when connecting the connector 100 to the PCB 10 and/or the busbar 20. FIG. 4 shows a schematic view of the connector 100 connecting the PCB 10 and the busbar 20. As shown, the second outer side 120b can be seen. FIG. 5 shows multiple connectors 100 connecting the PCB 10 and the busbar 20.

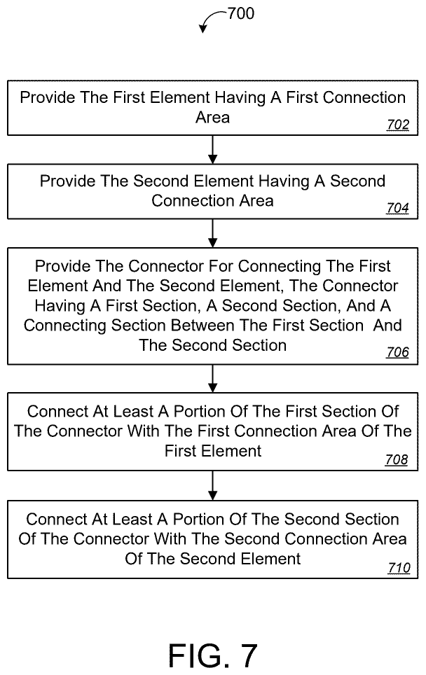

FIG. 7 provides an example arrangement of operations for a method 700 of connecting a first element 10, such as, but not limited to a PCB, and a second element, such as, but not limited to a busbar 20, using the connector of FIGS. 1-6. At block 702, the method 700 includes providing the first element 10 having a first connection area. At block 704, the method 700 includes providing the second element 20 having a second connection area. In addition, the method 700 at block 706 includes providing the connector 100 for connecting the first element 10 and the second element 20. The connector 100 includes a first section 110, a second section 120, and a connection section 130 between the first section 110 and the second section 120. At block 708, the method 700 includes connecting at least a portion of the first section 110 of the connector 100 with the first connection area of the first element 10. In addition, at block 710, the method 700 includes connecting at least a portion of the second section 120 of the connector 100 with the second connection area of the second element 20.

In some implementations, connecting the portion of the first section 110 of the connector 100 with the first connection area includes soldering the portion of the first section 110 of the connector with the first connection area by way of SMT technology. Connecting the portion of the second section 120 of the connector 100 with the second connection area may include welding the portion of the second section 120 of the connector 100 with the second connection area.

In some examples, providing the connector 100 for connecting the first element 10 and the second element 2 further includes: providing a tape reel having multiple connectors 100; and removing one of the multiple connectors 100 from the tape reel as the connector 100.

A number of implementations have been described. Nevertheless, it will be understood that various modifications may be made without departing from the spirit and scope of the disclosure. Accordingly, other implementations are within the scope of the following claims.

1. A connector for connecting a first element and a second element, the connector comprising:
a first section having a first length, the first section configured for attachment to the first element;
a second section having a second length, the second length being greater than the first length, the second section configured for attachment to the second element; and
a connection section connecting the first section and the second section such that the first section and the second section are each extending away from the connection section.

2. The connector of claim 1, wherein the first element is a PCB.

3. The connector of claim 1, wherein the second element is a busbar.

4. The connector of claim 1, wherein the first section is substantially parallel to the second section.

5. The connector of claim 1, wherein:
the first section includes a first inner side and a first outer side;
the second section includes a second inner side and a second outer side, the first inner side facing the second inner side.

6. The connector of claim 5, wherein the first inner side and the second inner side define a receptacle.

7. The connector of claim 5, wherein the second inner side of the second section includes a distal end for attachment to the second element.

8. The connector of claim 5, wherein at least a portion of the first outer side of the first section is configured for attachment to the first element.

9. A method of connecting a first element and a second element by way of a connector, the method comprising:
providing the first element having a first connection area;
providing the second element having a second connection area;
providing the connector for connecting the first element and the second element, the connector having a first section, a second section, and a connection section between the first section and the second section;
connecting at least a portion of the first section of the connector with the first connection area of the first element; and
connecting at least a portion of the second section of the connector with the second connection area of the second element.

10. The method of claim 9, wherein connecting the portion of the first section of the connector with the first connection area comprises:
soldering the portion of the first section of the connector with the first connection area.

11. The method of claim 9, wherein connecting the portion of the second section of the connector with the second connection area comprises:
welding the portion of the second section of the connector with the second connection area.

12. The method of claim 9, wherein providing the connector for connecting the first element and the second element further includes:
providing a tape reel having multiple connectors; and
removing one of the multiple connectors from the tape reel as the connector.

13. The method of claim 9, wherein the first element is a PCB.

14. The method of claim 9, wherein the second element is a busbar.
